(19) United States
(12) Patent Application Publication
(10) Pub. No.: US 2004/0146080 A1
(43) Pub. Date: Jul. 29, 2004

(54) Semiconductor laser apparatus

(75) Inventors: Toshitaka Yamada, Tokyo (JP); Hideaki Okano, Fukaya-shi (JP)

Correspondence Address: PILLSBURY WINTHROP, LLP, P.O. BOX 10500, MCLEAN, VA, 22102, US

(73) Assignee: KABUSHIKI KAISHA TOSHIBA, Tokyo (JP)

(21) Appl. No.: 10/743,254

(22) Filed: Dec. 23, 2003

(30) Foreign Application Priority Data
Dec. 26, 2002 (JP) 2002-378280

(51) Int. Cl. H01S 5/00

(52) U.S. Cl. 372/46; 372/45

(57) ABSTRACT

The present invention has the feature that, in a semiconductor laser apparatus having a negative electrode and a positive electrode sandwiching an active region (active region layer), and an optical resonance chamber which is defined by a high-reflecting mirror and an output mirror positioned at the both end portions thereof, the positive electrode and an oscillation optical axis which is the axis of the optical resonance chamber are made so as to be non-parallel.

### CROSS-REFERENCE TO RELATED APPLICATIONS

This application is based upon and claims the benefit of priority from the prior Japanese Patent Application No. 2002-378280, filed Dec. 26, 2002, the entire contents of which are incorporated herein by reference.

### BACKGROUND OF THE INVENTION

1. Field of the Invention

The present invention relates to a high power semiconductor laser apparatus, and in particular, to a semiconductor laser apparatus in which the laser beam quality in the transverse direction is improved.

2. Description of the Related Art

As a semiconductor laser apparatus, a wide variety of methods are described in detail, for example, in “Semiconductor laser” by Baifukan Co., Ltd, 1989, pp. 91 to 123.

The semiconductor laser apparatus has advantages such as compactness, high-speed, high-efficiency, long life, and the like. Further, the semiconductor laser apparatus can obtain a several watt class laser output by one emitter (a single emitter), and is used for processing of materials such as, for example, welding, hardening, marking, or the like, in addition to the case of use in the field of communication and the field of information processing.

However, in the semiconductor laser apparatus of the single emitter method, the laser output is limited to watt class in order to prevent generation of undesired damage or the like.

For example, in “IEEE Journal of Quantum Electronics, vol. 24, No. 6”, 1988, pp. 883 to 894, an array type semiconductor laser in which a plurality of emission points are set in array is disclosed. Note that there are cases in which the array type semiconductor laser is called a laser bar.

In the array type semiconductor laser, it is shown that, due to an active layer region sandwiched by two cladding layers being formed so as to have a length, for example, of about 10 mm, and due to a plurality of electrode stripes being disposed so as to be parallel to each other in the active layer region, a laser output stipulated as a multiple of the number of electrode stripes can be obtained (multi-stripe method).

Note that an output of several tens of watts to several hundred watts is realized by the laser bar, i.e., the array type semiconductor laser.

By the way, the quality of a laser beam is evaluated by the product of emission size and angle of divergence of the laser beam. The smaller than value the product of emission size and angle of divergence of the laser beam is, the higher the quality of the laser beam is.

Most of the semiconductor laser apparatuses which are available have a single electrode stripe, and have a gain waveguide structure in the transverse direction.

The quality of a laser beam in the vertical direction which can be obtained by the several watt class semiconductor laser apparatus is, for example, (a product of) 1.5 μm beam diameter and 40° angle of divergence.

On the other hand, the quality of the laser beam in the transverse direction is, for example, (a product of) 200 μm beam diameter and 9° angle of divergence. Accordingly, the quality of the laser beam in the transverse direction is markedly lower than the quality of the laser beam in the vertical direction.

The laser beam output from the semiconductor laser apparatus is used in the fields of communication and information (processing), and for processing of materials, which were described above, and in addition, is used for, for example, the light sources of a data projector and a projection television receiver as well.

When the semiconductor laser apparatus is used for the light sources of a data projector and a projection television receiver, a laser beam output from the semiconductor laser apparatus is condensed by a lens, and is made to be incident in an optical fiber using a core in which luminescent ions such as Pr₃⁺ (praseodymium ion), Tm₃⁺ (thulium ion), or the like, are mixed, and is efficiently converted from an infrared wavelength output by the semiconductor laser to a visible wavelength.

However, there are a large number of cases in which the diameter of the core of the optical fiber is less than or equal to 30 μm, and taking into consideration of the incident efficiency of the laser beam incident in the fiber, the diameter of the core of the optical fiber is converted into about 0.3 as a numerical aperture NA.

On the other hand, when a width in the transverse direction of the laser beam output from the semiconductor laser apparatus is 200 μm and the angle of divergence thereof is 9°, the minimum diameter (minimum beam diameter) is a little less than 60 μm.

Therefore, with respect to an optical fiber having a core diameter less than or equal to the minimum beam diameter, there is the problem that efficiency (coupling efficiency) when the laser beam incident in the optical fiber from the semiconductor laser apparatus is input to the optical fiber deteriorates (coupling loss increases).

This is in the same way as in the array type semiconductor laser and a stack type semiconductor laser, and further, because they have a structure in which a laser beam outputted from the single emitter semiconductor laser apparatus is made double in the transverse (active layer region) direction, the angle of divergences thereof are large, and they have large emission sizes. Note that, recently, a stack type semiconductor laser in which a plurality of array type semiconductor lasers are stacked in the vertical direction has been prepared. The stack type semiconductor laser realizes high output power of the kilowatt class.

However, in the array type semiconductor laser and the stack type semiconductor laser, the quality of a laser beam deteriorates as the number of the emitters increases.

In particular, in the array type semiconductor laser apparatus shown in “IEEE Journal of Quantum Electronics, vol. 24, No. 6”, there is the problem that, in addition to the fact that the quality of the laser beam by one electrode stripe is not sufficient, the light source size thereof grows in proportion to the number of the electrode stripes.

Due to such a situation, it is virtually impossible for the laser beam output from the semiconductor laser apparatus to be incident at a high coupling efficiency in a micro optical fiber, for example, an optical fiber whose core diameter is less than or equal to 50 μm.

Therefore, it is urgently necessary to improve the quality in the transverse (active layer region) direction of the laser beam from the semiconductor laser which can obtain a laser beam which is larger than that of the single emitter type semiconductor laser such as the array type semiconductor laser, the stack type semiconductor laser, or the like.

Note that, when the array type semiconductor laser apparatus and the stack type semiconductor laser apparatus are structured so as to have the structure shown in “IEEE Journal of Quantum Electronics, vol. 24, No. 6”, a plurality of total reflection mirrors must be provided at the exteriors thereof, and there is the problem that the optical systems thereof are made complicated.

### BRIEF SUMMARY OF THE INVENTION

According to the present invention, there is provided a semiconductor laser apparatus which has a slab waveguide structure extended in one direction, and in which a gain waveguide structure is formed in a direction vertical to the one direction, and in which a first electrode stipulating the gain waveguide along an oscillation optical axis of an optical resonator and a plane-shaped second electrode are disposed so as to face one another, wherein the first electrode is formed so as to have a predetermined angle with respect to the oscillation optical axis.

According to the present invention, there is further provided a semiconductor laser apparatus comprising: a first semiconductor layer which is a plate-shaped p-type semiconductor, and in which a first electrode is formed on an entire surface at one side; a first mirror which is provided at one end in a direction in which a surface of the first semiconductor layer is extended, in a direction perpendicular to the direction in which the surface is extended; a second mirror which is provided at one end in the direction in which the surface of the first semiconductor layer is extended, in a direction perpendicular to the direction in which the surface is extended and so as to be parallel to the first mirror; a second semiconductor layer which is a plate-shaped n-type semiconductor, and which is extended, at one side surface so as to be a predetermined shape, to at least one side of the direction in which the one side surface is extended, and on which a second electrode which is able to face the first electrode is formed, the second electrode being formed so as to have a predetermined angle with respect to a straight line defined due to the first mirror and the second mirror facing one another; and an active layer positioned between a plane facing the plane on which the first electrode of the first semiconductor layer is formed and a plane facing the plane on which the second electrode of the second semiconductor layer is formed, the active layer outputting light in a direction perpendicular to the plane direction of the first and second semiconductor layers and in a direction parallel to the straight line defined by the first mirror and the second mirror due to a predetermined amount of electric current being supplied to the second electrode.

According to the present invention, there is still further provided a semiconductor laser apparatus comprising: a first semiconductor layer which functions as one cladding layer of an array waveguide, and in which a negative electrode is formed on an entire surface of one side; a first mirror which is provided at one end in a direction to which a surface of the first semiconductor layer is extended, in a direction perpendicular to the direction in which the surface is extended; a second mirror which is provided at one end in the direction in which the surface of the first semiconductor layer is extended, in a direction perpendicular to the direction in which the surface is extended and so as to be parallel to the first mirror; a second semiconductor layer which functions as a second cladding layer facing the first semiconductor layer of the array waveguide, and which is extended, at a surface opposite to the surface facing the first semiconductor layer so as to be a predetermined shape, to at least one side of the direction in which the one side surface is extended, and on which a positive electrode which is able to face the negative electrode is formed, the positive electrode being non-parallel to a straight line defined due to the first mirror and the second mirror facing one another; and an active layer positioned between a plane facing the plane on which the first electrode of the first semiconductor layer is formed and a plane facing the plane on which the second electrode of the second semiconductor layer is formed, the active layer outputting light in a direction perpendicular to the plane direction of the first and second semiconductor layers and in a direction parallel to the straight line defined by the first mirror and the second mirror due to a predetermined amount of electric current being supplied to the second electrode.

### BRIEF DESCRIPTION OF THE SEVERAL VIEWS OF THE DRAWING

The accompanying drawings, which are incorporated in and constitute a part of the specification, illustrate embodiments of the invention, and together with the general description given above and the detailed description of the embodiments given below, serve to explain the principles of the invention.

FIG. 1 is a schematic diagram for explanation of an example of a semiconductor laser apparatus to which an embodiment of the present invention can be applied;

FIG. 2 is a schematic diagram for explanation of a phase difference in an oscillation optical axis direction of a laser beam in the semiconductor laser apparatus shown in FIG. 1;

FIG. 3 is a schematic diagram for explanation of laser output power and angle of divergences when an angle of inclination of an electrode stripe is made to change in the semiconductor laser apparatus shown in FIG. 1;

FIG. 4 is a schematic diagram for explanation of radiant characteristics in the vertical direction of the semiconductor laser apparatus shown in FIG. 1;

FIG. 5 is a schematic diagram for explanation of radiant characteristics in the transverse direction of the semiconductor laser apparatus shown in FIG. 1;

FIG. 6A is a schematic diagram for explanation of a structure in the transverse direction of the semiconductor laser apparatus shown in FIG. 1;

FIG. 6B is a schematic diagram for explanation of a refractive index profile in the semiconductor laser apparatus having the structure of the transverse direction shown in FIG. 6A;

FIG. 6C is a schematic diagram for explanation of a gain and loss distribution in the semiconductor laser apparatus having the structure of the transverse direction shown in FIG. 6A;

FIG. 6D is a schematic diagram for explanation of characteristics of a wave front in the semiconductor laser apparatus having the structure of the transverse direction shown in FIG. 6A;

FIGS. 7A to 7D are schematic diagrams for explanation of a modified example of a first electrode which can be applied to the semiconductor laser apparatus shown in FIG. 1;

FIG. 8 is a schematic diagram for explanation of another example of the semiconductor laser apparatus to which the embodiment of the present invention can be applied;

FIG. 9 is a schematic diagram for explanation of even another example of the semiconductor laser apparatus to which the embodiment of the present invention can be applied;

FIG. 10 is a schematic diagram for explanation of an example of a semiconductor laser apparatus compared with the semiconductor laser apparatus of the present invention shown in FIGS. 1 to 5 and 6A to 6D;

FIG. 11A is a schematic diagram for explanation of a structure in the transverse direction of the semiconductor laser apparatus shown in FIG. 10;

FIG. 11B is a schematic diagram for explanation of a refractive index profile in the semiconductor laser apparatus having the structure of the transverse direction shown in FIG. 11A;

FIG. 11C is a schematic diagram for explanation of a gain and loss distribution in the semiconductor laser apparatus having the structure of the transverse direction shown in FIG. 11A; and

FIG. 11D is a schematic diagram for explanation of characteristics of wave front in the semiconductor laser apparatus having the structure of the transverse direction shown in FIG. 11A.

### DETAILED DESCRIPTION OF THE INVENTION

Hereinafter, one example of a fiber laser apparatus to which an embodiment of the present invention is applied will be described with reference to the drawings.

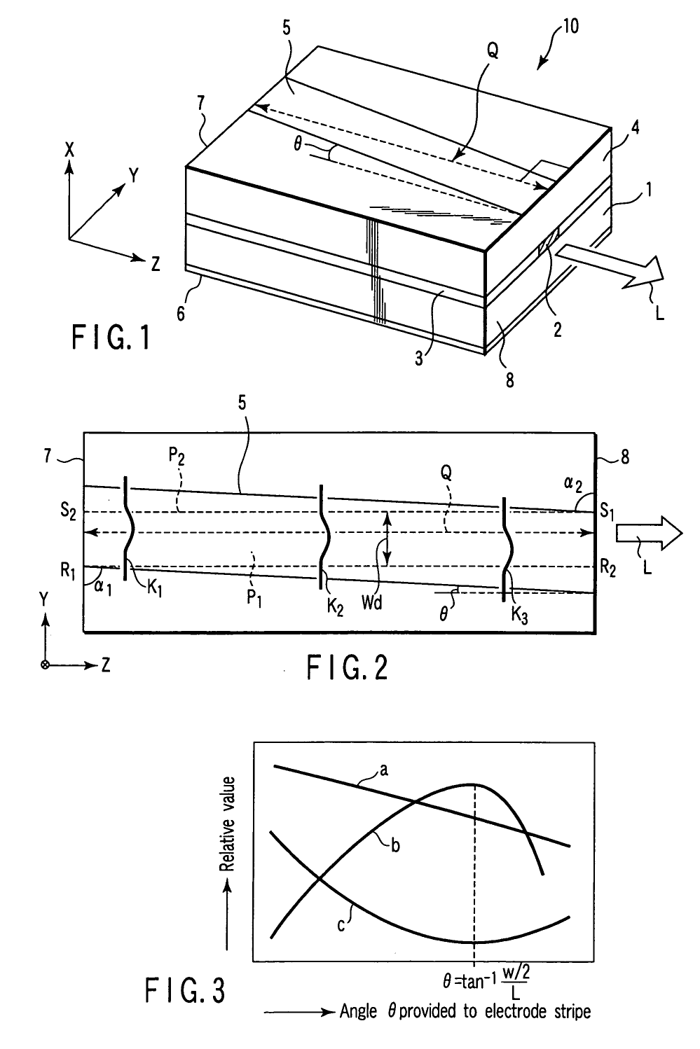

FIG. 1 is a block diagram of a semiconductor laser apparatus having a single emitter.

At a semiconductor laser apparatus 10, a layer 3 (hereinafter active region layer) having a p-type active region 2 is formed on an n-type cladding layer 1, and a p-type cladding layer 4 is formed on the active region layer 3. The active region layer 3 and the cladding layer 4 are laminated on X direction (hereinafter referred to as vertical direction).

The n-type cladding layer 1 is made from, for example, Al—Ga—As, and the active region layer 3 is made from, for example, Ga—As, and the p-type cladding layer 4 is made from, for example, Al—Ga—As. A light refractive index of the active region layer 3 is higher than those of the respective cladding layers 1 and 4. The active region layer 3 is formed, for example, such that the thickness thereof is less than or equal to 1 μm.

A stripe-shaped electrode (first electrode, and hereinafter, referred to as electrode stripe) 5 is formed on the top surface of the cladding layer 4. The electrode stripe (first electrode) 5 is formed so as to have a predetermined width which is, for example, several μm to several hundred am, and so as to be inclined by a predetermined angle θ, e.g. 0.5° to 5°, with respect to the optical axis in the transverse direction plane with respect to an oscillation optical axis Q (Z direction) of a laser beam. Note that the electrode stripe 5 is a positive electrode.

A plane negative electrode 6 is formed on the bottom surface of the cladding layer 1. The negative electrode 6 is a negative electrode.

A high-reflecting mirror surface 7 and an output mirror surface 8 which form an optical resonator are respectively formed at the end faces in the optical axis direction. The high-reflecting mirror surface 7 and the output mirror surface 8 are disposed so as to face one another. Further, a direction in which the high-reflecting mirror surface 7 and the output mirror surface 8 face one another is substantially parallel to the oscillation optical axis Q.

At the semiconductor laser apparatus 10 described above, in the vertical direction, the active region 2 of the active layer 3 is surrounded with. Accordingly, electric current and light which are made to flow from the electrode stripe 5 to the negative electrode 6 are confined in the substantially central vicinity of the active region 2, since the band gap and refractive index are different from with the cladding layer 1, the active region layer 3, and the cladding layer 4. Namely, the vertical direction is a slab waveguide structure (refractive index waveguide structure). A carrier recombination light generation arises at the active region 2.

The transverse direction (Y direction), i.e., the junction direction of the cladding layer 1, the active region layer 3, and the cladding layer 4 (a direction parallel to the pn junction) is formed so as to be a uniform material. In the transverse direction, a region at which electric current is made to flow is limited in accordance with a width of the electrode stripe 5. Because the transverse direction guides light by gain and loss due to a size of current density, the transverse direction is called gain waveguide.

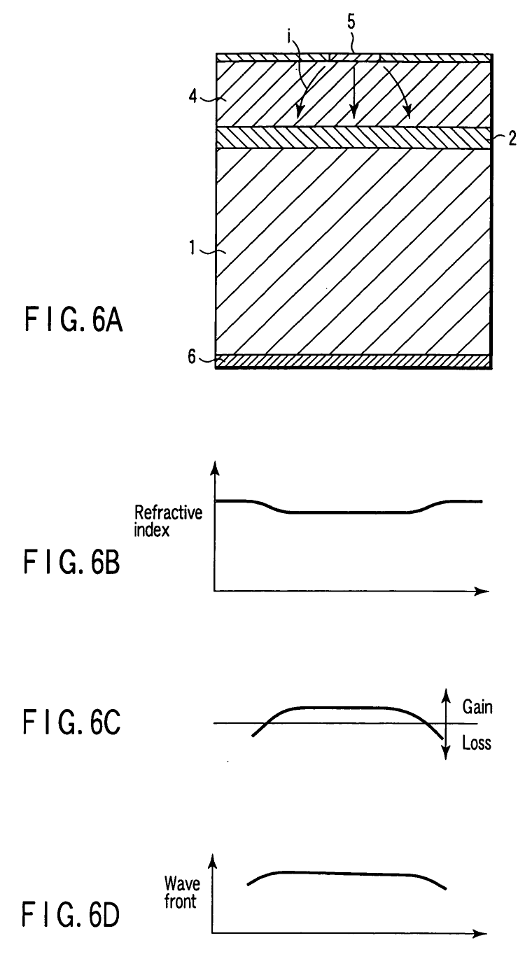

Namely, in the semiconductor laser apparatus having a single emitter shown in FIG. 1, i.e., the single emitter semiconductor laser apparatus, a beam width of a laser beam which is made to oscillate (outputted) due to the electrode stripe 5 being inclined at a predetermined angle θ, for example, about 1° with respect to the oscillation optical axis Q determined by the resonator mirrors (the mirror 7 and the mirror 8) is consistent with a width of a region shown by “gain” in FIG. 6C.

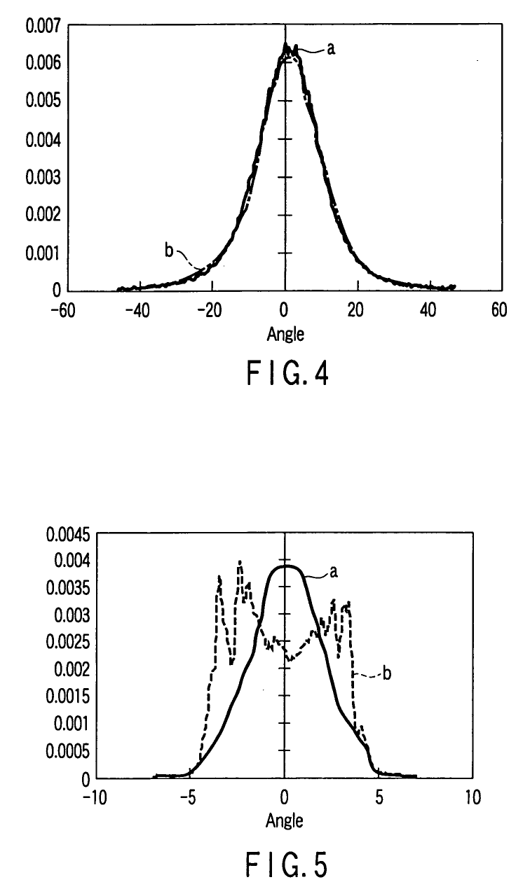

By the way, the quality of the laser beam output from the semiconductor laser apparatus which can output W class laser output P will be described later by using FIGS. 4 and 5. However, as is clear from the respective curves b (broken lines), the quality of the laser beam is greatly different in accordance with the pn junction surface direction (transverse direction) between the cladding layer 1 and the cladding layer 4 and the direction vertical to the pn junction surface (vertical direction). When the differences of the qualities of the laser beam are numerized, about 20 times difference can be recognized. Namely, because the vertical direction is the refractive index waveguide structure, an emission size of the laser beam is small, and therefore, the quality of the laser beam is high.

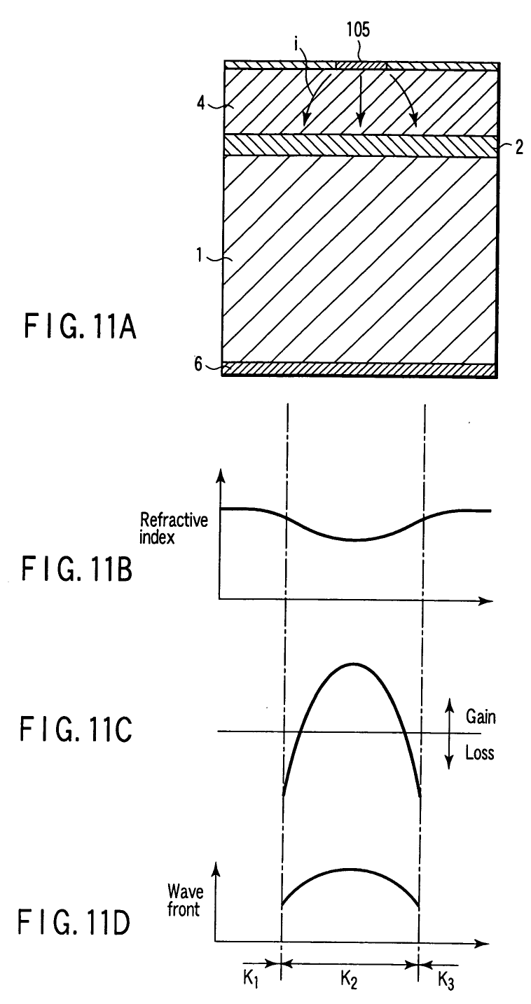

On the other hand, because the transverse direction is the gain waveguide structure, the transverse direction becomes anti-waveguide, and as described by FIGS. 11B and 1D, a wave front of the laser beam oscillating on the oscillation optical axis of the semiconductor laser apparatus is made to be a convex shape. Therefore, a angle of divergence of the laser beam output from the semiconductor laser apparatus is large, and the quality of the laser beam is low.

As shown in FIGS. 4, 5, and 6A to 6D, the laser beam radiated from the semiconductor laser apparatus 10 is markedly different in accordance with the respective radiant characteristics in the vertical direction and the transverse direction. Note that, FIG. 4 shows radiant characteristics in the vertical direction of the semiconductor laser apparatus, and that FIG. 5 shows radiant characteristics in the transverse direction of the semiconductor laser apparatus.

FIG. 6A shows a transverse direction structure of the semiconductor laser apparatus, FIG. 6B shows a refractive index profile in the semiconductor laser apparatus having the structure shown in FIG. 6A, FIG. 6C shows a gain and loss distribution in the semiconductor laser apparatus, and FIG. 6D shows characteristics of a wave front in the semiconductor laser apparatus.

As is clear from FIGS. 4, 5, and 6A to 6D, the radiant characteristics of the laser beam in the vertical direction show level variations which are symmetrical to angles, and it can be recognized that the quality thereof is high. On the other hand, the radiant characteristics of the laser beam in the transverse direction show level variations which are ununiform with respect to angles, and it can be recognized that the quality thereof is low as compared with that in the vertical direction.

Here, the reason that the quality of the laser beam in the transverse direction deteriorates will be described.

FIGS. 11A to 11D are schematic diagram of a structure in the transverse direction of the semiconductor laser apparatus shown in FIG. 10 for compare with the semiconductor laser apparatus of the present invention of FIG. 1.

FIG. 11A shows a structure of the transverse direction of a general semiconductor laser apparatus which is compared with the semiconductor laser apparatus of the present invention, FIG. 11B shows a refractive index profile in the transverse direction of laser beam output from the laser apparatus shown in FIG. 11A, FIG. 11C shows a gain and loss distribution of the laser beam, and FIG. 11D shows characteristics of a wave front in the laser beam.

A width of an electrode stripe 105 is, for example, 50 through 400 μm. An electric current i injected from the electrode stripe 105 is made to flow toward to the broad negative electrode 6 which is at opposite position. With respect to current density distribution in the transverse direction at this time, the central portion thereof is high, and as the current density distribution approaches the peripheral portion, the current density distribution becomes monotonously low.

For example, as the relationship between refractive indices and carrier concentrations (injection current densities) is shown in “J. Appl. Physics, vol. 44, No. 10, 1973, pp. 4696 to 4707”, a refractive index n is a function of a carrier concentration N, and the relationship between the refractive index and the carrier concentration can be expressed by:

n≈n₀(1−N·e²/2m·ε₀·ω²·n₀) (1)

wherein n₀ is a refractive index when there is no carrier; e is an electric charge of an electron; m is an effective mass of an electron, ε₀ is a vacuum dielectric constant; and ω is a frequency of light.

Expression (1) shows the relationship in which, when the carrier concentration N is made large, refractive index n becomes low.

(In FIG. 11B,) K₁ to K₃ respectively show refractive index profiles in the transverse direction at the arbitrary respective points. The refractive index profiles K₁ to K₃ are respectively low at the central portions, and as the refractive index profiles approaches the peripheral portions, the refractive indices in a state in which there is no carrier, i.e., the refractive indices of the materials themselves increase. The central position of the refractive index profiles K₁ to K₃ is shifted in the transverse direction in accordance with the inclined electrode stripe 5. Namely, as shown in FIG. 11B, variations in the transverse direction in the refractive index n are low at the central portion, and as the refractive index n approaches the peripheral portion, the refractive index in a state in which there is no carrier, i.e., the refractive index of the material itself increases.

Such a refractive index profile in the transverse direction provides an action effect which is the same as the concave lens to the laser beam with respect to the oscillation optical axis shown in FIG. 11A (in the direction vertical to the drawing). Therefore, the transverse direction becomes a waveguide structure which is called anti-waveguide.

Accordingly, as shown in FIG. 1D, by the transverse direction refractive index profile, a wave front of the laser beam in the traveling direction (optical axis direction) becomes convex shape such that the vicinity of the electrode stripe 105 is the top portion. Therefore, the laser beam is made such that the angle of divergence thereof is large in the transverse direction, and the quality of the laser beam deteriorates.

Note that, because even the anti-waveguided waveguide structure has a large gain along the electrode stripe 105, the power of the laser beam in the transverse direction is made large.

On the other hand, at the semiconductor laser apparatus 10 of the present invention which is described in FIG. 1 or the like, the electrode stripe (first electrode) 5 is formed so as to be inclined within a range of an angle θ, e.g. 0.5° to 5°, with respect to the oscillation optical axis Q of the laser beam. The best angle of inclination θ of the electrode stripe 5 is an angle which is determined by:

θ=tan⁻¹((W/2)/L) (2)

wherein W is a width of the electrode stripe 5; and L is a length of the electrode stripe 5.

The light generated in the active region 2 optically oscillates between the high-reflecting mirror surface 7 and the output mirror surface 8, and at a point in time when predetermined conditions are satisfied, a laser beam can be obtained from the output mirror surface 8.

At this time, a transverse direction width Wd of the laser beam laser-oscillating is equal to the width of the portion in which the electrode stripe 5 is not cut away in the Z direction in the electrode stripe 5 which is inclined (disposed at an angle θ with respect to the optical axis Q).

Namely, edge points R₁ and S₁ are respectively set at the respective end faces of the high-reflecting mirror surface 7 and the output mirror surface 8 in the electrode stripe 5.

The one edge point R₁ is a point at which an angle α₁ determined by the high-reflecting mirror surface 7 and the edge line of the electrode stripe 5 is made to be less than or equal to 90°, and the other edge point S₁ is a point at which an angle α₂ determined by the output mirror surface 8 and the edge line of the electrode stripe 5 is made to be less than or equal to 90°.

It is supposed that the intersection between the line extended from the edge point R₁ in Z direction and the output mirror surface 8 is an end point R₂, and in the same way, it is supposed that the intersection between the line extended from the other edge point S₁ to Z direction and the high-reflecting mirror surface 7 is an end point S₂. Accordingly, a width of Y direction of the line connecting the edge point R₁ and the end point R₂ and the line connecting the edge point S₁ and the end point S₂ is the laser beam width Wd.

Here, a phase difference of the laser beam in the oscillation optical axis Q direction will be described.

A first optical path P₁ is supposed on the line connecting the edge point R₁ and the end point R₂ shown in FIG. 2, and a second optical path P₂ is supposed on the line connecting the edge point S₁ and the end point S₂. At this time, the first optical path P₁ and the second optical path P₂ are on the optical paths which are separated from and parallel to one another within the laser beam width Wd.

A difference in the optical path lengths of the first optical path P₁ and the second optical path P₂, i.e., a phase difference Δφ can be expressed by the following expression.

Δφ=∫₂(k·n)d1−∫₁(k·n)d1 (3)

The refractive index n expressed by expression (3) is approximately expressed by the following expression (4) as a function of a position y in the transverse direction:

n(y)=n₀−p·y² (4)

wherein p is a fixed number as a square distribution.

Even when a variation in the refractive index n is offset from the square distribution, it suffices that the variation in the refractive index n is a smoothly symmetrical function.

Namely, the sizes of the refractive indices of the points on which the respective lights on the first optical path P₁ and the second optical path P₂ pass vary as the lights progress toward the Z direction.

The phase of the laser beam can be calculated by an amount in which a wave number k and the refractive index n are integrated. The respective lights on the first optical path P₁ and the second optical path P₂ respectively pass at the inclined portions of the refractive index profiles.

In accordance therewith, seeing from the midpoint on the oscillation optical axis Q in the optical resonator, inclinations of the respective refractive index profiles at the high-reflecting mirror surface 7 side and the output mirror surface 8 side are reverse inclinations.

Namely, the inclination on the oscillation optical axis Q at the refractive index profile K₁ (which has been described in FIG. 11B) falls from the left side toward the right side (can be described such that the inclination rises from the right side toward the left side), and the inclination on the oscillation optical axis Q at the refractive index profile K₃ rises from the left side toward the right side (can be described such that the inclination falls from the right side toward the left side).

Here, as shown in FIG. 6B, the entire refractive index profile in the transverse direction is averaged over the entire optical path length of the oscillation optical axis Q of the laser beam. Namely, if a difference is obtained due to the entire refractive index profile being integrated over the entire optical path length, the difference becomes minimum.

This shows that a phase difference is small over the entire optical path length of the oscillation optical axis Q of the laser beam. Accordingly, as shown in FIG. 6D, a plane wave which is substantially parallel to the oscillation optical axis Q direction of the laser beam can be obtained. That is, the semiconductor laser apparatus of the present invention can output a laser beam whose angle of divergence in the transverse direction is small. As shown in FIG. 6C, the gain and loss distribution of the laser beam is substantially flat (as compared with the laser beam already described by FIG. 1C).

FIG. 3 shows the output power of the laser beam, the angle of divergence of the laser beam, and the luminance in the same direction when the angle of inclination θ of the electrode stripe 5 is changed. In FIG. 3, the abscissa is the angle of inclination θ, and the ordinate is the output power, the angle of divergence, and the luminance of the laser beam.

In FIG. 3, a curve a denotes output power of the semiconductor laser apparatus of the present invention, a curve b denotes a change of luminance of laser beam and a curve c denotes a change of divergence of angle of the laser beam.

As can be known from FIG. 3, when the angle of inclination is made large, the output power of the laser beam deteriorates. This is because, when the angle of inclination, i.e., θ is made large, the overlap of the laser beam and the gain region is made small. On the other hand, the size of the angle of divergence is getting to increase with an angle determined by expression (2) “θ=tan⁻¹ ((W/2)/L)” being minimum (when the angle is θ, the luminance is the maximum).

In accordance therewith, when the width W=200 μm, the length L=1000 μm, the semiconductor laser apparatus of the present invention obtains the maximum luminance at an angle of inclination of about 4°.

As a result, the semiconductor laser apparatus of the present invention can make the angle of divergence of the laser beam less than or equal to ¼ of that of the prior art, and can improve the luminance three times or more than that of the prior art.

In this way, in the semiconductor laser apparatus shown in FIG. 1, because the electrode stripe 5 is formed so as to be inclined in the transverse direction plane with respect to the oscillation optical axis Q of the laser beam (such that the positive electrode and the oscillation optical axis which is the axis of an optical resonating room are non-parallel), even the semiconductor laser apparatus having a gain waveguide structure in the transverse direction by using the electrode stripe 5 can largely improve the transverse direction quality of the laser beam (refer to curve “a” of FIG. 5). Also, the luminance can be markedly improved. Namely, in the semiconductor laser apparatus, because the quality of the laser beam in the vertical direction is originally high (refer to curve “a” of FIG. 4), due to the quality of the laser beam in the transverse direction being improved, the entire quality of the laser beam can be improved while maintaining the output (power).

As described above, the numerical aperture of the laser beam outputted from the semiconductor laser apparatus of the present invention can be made small by being condensed by a condenser lens or the like. In accordance therewith, the high output laser beam from the semiconductor laser apparatus can be high-efficiently combined with respect to a narrow core diameter optical fiber having a core diameter of, for example, a little less than 20 μm. As a result, the semiconductor laser apparatus of the present invention can be applied to a broad range of fields.

For example, it goes without saying that the laser beam outputted from the semiconductor laser apparatus can be used in the field of communication and the field of information (processing), or for processing of materials, and the laser beam output from the semiconductor laser apparatus can be used for, for example, an excitation source, as well, of an up-conversion fiber laser which is a light source of visible radiation required for a projector. In particular, when the laser beam is used for a projector, it is demanded that the high power laser beam is high-efficiently transmitted through a small core diameter optical fiber, and visible radiation is generated. However the demand is sufficiently satisfied.

Further, in the semiconductor laser apparatus of the present invention, because the quality of the laser beam in the transverse direction is improved, there is no need to separately provide a total reflection mirror at the exterior of the semiconductor laser apparatus. Accordingly, the semiconductor laser apparatus of the present invention can improve the quality of the laser beam in the transverse direction without an optical element being provided at the exterior thereof, and without compactness and speed properties which are the features of the semiconductor laser apparatus being lost.

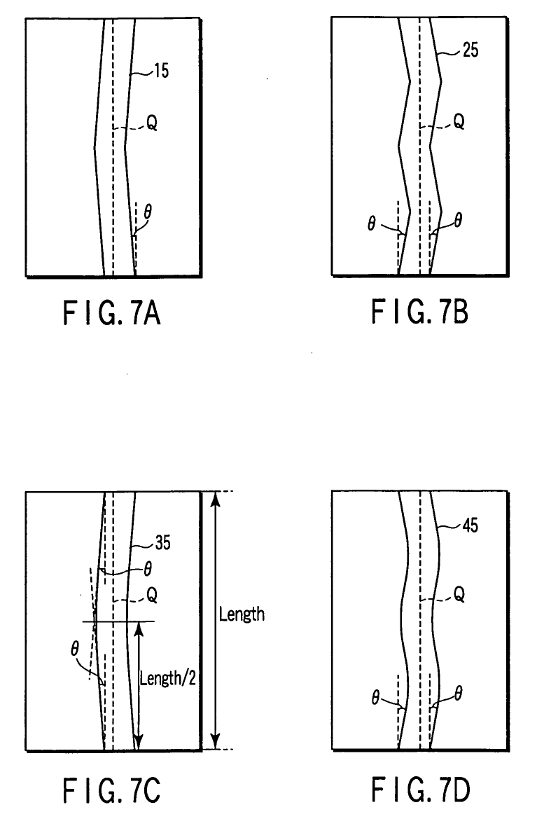

Note that as the feature of the shape of the electrode stripe, various shapes which will be described hereinafter by FIGS. 7A to 7D can be considered.

A first electrode 15 shown in FIG. 7A has a structure formed so as to be a “V shape” (as a sign of inequality in mathematics) shape on the oscillation optical axis Q of the laser beam.

In this case, the angle of inclination θ is preferably set to an angle which is:

θ=tan⁻¹((W/2)/(L/2)) (5)

Further, as shown in FIG. 7B, a first electrode 25 may be formed so as to be zigzag with respect to the oscillation optical axis Q of the laser beam. In this case, the angle of inclination θ is preferably:

θ=tan⁻¹((W/2)/(L/4)) (6)

A first electrode 35 shown in FIG. 7C is an example such that the first electrode 35 is formed at a predetermined curvature (or in a shape in which the curve portion and the straight line portion are synthesized) with respect to the oscillation optical axis Q of the laser beam. Note that the angle of inclination θ can be defined as an angle with respect to the tangent at the substantially central position in the length direction (½ of the length) of the electrode stripe 35. For example, further, the angle of inclination θ can be determined by expression (5).

Moreover, as shown in FIG. 7D, the first electrode 45 may be so as to be meandering with respect to the oscillation optical axis Q of the laser beam. In this case, the angle of inclination θ can be determined by expression (6).

FIG. 8 is a schematic diagram for explanation of another example of the semiconductor laser apparatus shown in FIG. 1. Note that, same portions which are the same as those of the structure (factors) described above by FIG. 1 are denoted by the same reference numerals, and detailed description thereof is omitted.

At an array type semiconductor laser apparatus 50 shown in FIG. 8, a plurality of electrode stripes 55-1 to 55-n are disposed on the cladding layer 4 so as to be inclined within a range of an angle θ, e.g. 0.50 to 50, in the plane which is transverse with respect to the respective oscillation optical axes Q of the respective laser beams, and so as to be parallel to each other.

The best angle of inclination θ of the electrode stripes 55-1 to 55-n is, for example, about 40 with respect to the oscillation optical axis Q of the laser beam. Concretely, the respective electrode stripes 55-1 to 55-n are made, for example, such that the widths thereof are less than or equal to 200 am, and intervals between one another is 300 μm, and the lengths thereof are 10 mm.

The semiconductor laser apparatus 50 can largely improve the qualities of the respective laser beams in the transverse direction in the same way as the semiconductor laser apparatus 10 described above.

Further, because the semiconductor laser apparatus 50 has the plurality of electrode stripes 55-1 to 55-n, a laser beam of a power (output) which is set in accordance with the multiples of the electrode stripes 55-1 to 55-n can be obtained. For example, the above-described semiconductor laser apparatus can output a laser beam having a luminance which is three times or more than that of the prior art by output power of about 60 W.

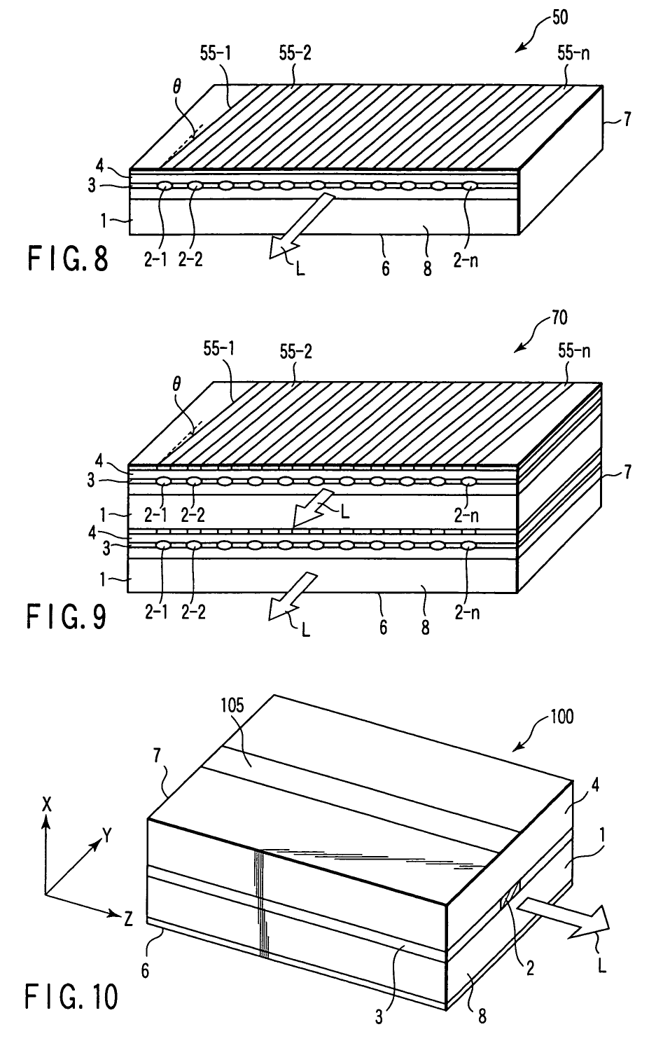

Note that the semiconductor laser apparatus 50 is an array type in which the plurality of electrode stripes 55-1 to 55-n are arranged so as to be inclined and be in parallel. However, as shown in FIG. 9, a stack type semiconductor laser apparatus 70 can be prepared due to a plurality of electrode stripes being further stacked in the vertical direction.

In accordance with the stack type semiconductor laser apparatus 70 shown in FIG. 9, high output power of the kilowatt class can be obtained, and a laser beam in which the quality of the laser beam in the transverse direction was largely improved can be obtained.

Note that the present invention is not limited to the above-described embodiment, and various modifications are possible within a range which does not deviate from the major characteristics of the present invention at the practical phase.

Moreover, inventions at various phases are included in the above-described embodiment, various inventions can be extracted due to a plurality of structural requirements which have been disclosed being appropriately combined. For example, provided that several structural requirements are eliminated from all of the structural requirements shown in the embodiment, when the problems described in the column of PROBLEMS TO BE SOLVED BY THE INVENTION can be solved, and the effect described in the column of EFFECT OF THE INVENTION can be obtained, the structure in which the structural requirements are eliminated can be extracted as an invention.

For example, the case has been described in which the electrode stripe 5 which is a single emitter is formed in the semiconductor laser apparatus 10, and the plurality of electrode stripes 55-1 to 55-n are formed in the semiconductor laser apparatus 50, and the transverse direction is made to be the gain waveguide type and the gain waveguide type is applied to the semiconductor laser apparatus are described. However, the present invention is not limited to this case, and can be applied to various gain waveguide type semiconductor laser apparatuses such as a Zn diffusion planar stripe structure, a proton placing structure, a V groove stripe structure, or the like.

Moreover, even if the semiconductor laser apparatus 10 is a refractive index waveguide type semiconductor laser apparatus, provided that the semiconductor laser apparatus is structured such that the gain waveguide type is superior due to electric current diffusion, the present invention can be applied to the semiconductor laser apparatus.

Further, provided that the electrode stripe 5 in the semiconductor laser apparatus 10 and the plurality of electrode stripes 55-1 to 55-n in the semiconductor laser apparatus 50 are respectively structured from, for example, elements of III-V group, II-IV group, the present invention can be applied to the semiconductor laser apparatuses regardless of an oscillation wavelength.

Note that it goes without saying that, even if the angle of inclination θ of the electrode stripe is inclined in any direction of right and left with respect to the oscillation optical axis Q, the same effect can be obtained.

In addition, provided that the electrode stripe 5 and the electrode stripes 55-1 to 55-n whose examples were shown in the respective semiconductor laser apparatuses are shapes in which the refractive index profile in the transverse direction is averaged over the entire optical path length of the oscillation optical axis Q of the laser beam, it goes without saying that the electrode stripe 5 and the electrode stripes 55-1 to 55-n can be formed so as to be arbitrary shapes of the electrodes 15, 25, 35, and 45 having the shapes which were described above by FIGS. 7A to 7D.

As described above in detail, in accordance with the present invention, a semiconductor laser apparatus which can improve the quality of the laser beam in the transverse direction can be obtained.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor laser apparatus which has a slab waveguide structure extended in one direction, and in which a gain waveguide structure is formed in a direction vertical to said one direction, and in which a first electrode stipulating the gain waveguide along an oscillation optical axis of an optical resonator and a plane-shaped second electrode are disposed so as to face one another, wherein the first electrode is formed so as to have a predetermined angle with respect to the oscillation optical axis.

2. A semiconductor laser apparatus according to claim 1, wherein at least one first electrode other than the first electrode is provided, and the respective electrodes are parallel to each other.

3. A semiconductor laser apparatus according to claim 1, wherein at least one first electrode other than the first electrode is provided, and the respective electrodes are parallel to each other, and a plurality of layers are further laminated.

4. A semiconductor laser apparatus according to claim 2, wherein the first electrode is formed such that, given that W is a width of the first electrode and L is a length of the first electrode, the angle θ is determined by θ=tan⁻¹ ((W/2)/(L/2)).

5. A semiconductor laser apparatus according to claim 2, wherein the first electrode includes a region in which, given that W is a width of the first electrode and L is a length of the first electrode, an inclination which can be defined by θ=tan⁻¹ ((W/2)/(L/4)) is provided.

6. A semiconductor laser apparatus according to claim 3, wherein the first electrode is formed such that, given that W is a width of the first electrode and L is a length of the first electrode, the angle θ is determined by θ=tan⁻¹ ((W/2)/(L/2)).

7. A semiconductor laser apparatus according to claim 3, wherein the first electrode includes a region in which, given that W is a width of the first electrode and L is a length of the first electrode, an inclination which can be defined by θ=tan⁻¹ ((W/2)/(L/4)) is provided.

8. A semiconductor laser apparatus according to claim 2, wherein the inclination of the first electrode is an angle in which a refractive index profile along the direction in which the gain waveguide structure is extended is averaged over the entire optical path length of the oscillation optical axis of the laser beam.

9. A semiconductor laser apparatus according to claim 3, wherein the inclination of the first electrode is an angle in which a refractive index profile along the direction in which the gain waveguide structure is extended is averaged over the entire optical path length of the oscillation optical axis of the laser beam.

10. A semiconductor laser apparatus comprising:
a first semiconductor layer which is a plate-shaped p-type semiconductor, and in which a first electrode is formed on an entire surface at one side;
a first mirror which is provided at one end in a direction in which a surface of the first semiconductor layer is extended, in a direction perpendicular to the direction in which the surface is extended;
a second mirror which is provided at one end in the direction in which the surface of the first semiconductor layer is extended, in a direction perpendicular to the direction in which the surface is extended and so as to be parallel to the first mirror;
a second semiconductor layer which is a plate-shaped n-type semiconductor, and which is extended, at one side surface so as to be a predetermined shape, to at least one side of the direction in which said one side surface is extended, and on which a second electrode which is able to face the first electrode is formed, the second electrode being formed so as to have a predetermined angle with respect to a straight line defined due to the first mirror and the second mirror facing one another; and
an active layer positioned between a plane facing the plane on which the first electrode of the first semiconductor layer is formed and a plane facing the plane on which the second electrode of the second semiconductor layer is formed, the active layer outputting light in a direction perpendicular to the plane direction of the first and second semiconductor layers and in a direction parallel to the straight line defined by the first mirror and the second mirror due to a predetermined amount of electric current being supplied to the second electrode.

11. A semiconductor laser apparatus according to claim 10, wherein at least one second electrode other than the second electrode is provided, and the respective electrodes are parallel to each other.

12. A semiconductor laser apparatus according to claim 10, wherein the angle provided to the second electrode is an angle in which a refractive index profile along the direction in which the active layer is extended can be averaged over the entire area of an optical path on which the light is outputted.

13. A semiconductor laser apparatus according to claim 11, wherein, given that W is a width of the second electrode and L is a length of the second electrode, the second electrode is formed so as to have an angle determined by θ=tan⁻¹ ((W/2)/L).

14. A semiconductor laser apparatus according to claim 12, wherein, given that W is a width of the second electrode and L is a length of the second electrode, an angle obtained by the second electrode and the straight line is an angle which is determined by θ=tan⁻¹ ((W/2)/L).

15. A semiconductor laser apparatus comprising:
a first semiconductor layer which functions as one cladding layer of an array waveguide, and in which a negative electrode is formed on an entire surface of one side;
a first mirror which is provided at one end in a direction to which a surface of the first semiconductor layer is extended, in a direction perpendicular to the direction in which the surface is extended;
a second mirror which is provided at one end in the direction in which the surface of the first semiconductor layer is extended, in a direction perpendicular to the direction in which the surface is extended and so as to be parallel to the first mirror;
a second semiconductor layer which functions as a second cladding layer facing the first semiconductor layer of the array waveguide, and which is extended, at a surface opposite to the surface facing the first semiconductor layer so as to be a predetermined shape, to at least one side of the direction in which said one side surface is extended, and on which a positive electrode which is able to face the negative electrode is formed, the positive electrode being non-parallel to a straight line defined due to the first mirror and the second mirror facing one another; and
an active layer positioned between a plane facing the plane on which the first electrode of the first semiconductor layer is formed and a plane facing the plane on which the second electrode of the second semiconductor layer is formed, the active layer outputting light in a direction perpendicular to the plane direction of the first and second semiconductor layers and in a direction parallel to the straight line defined by the first mirror and the second mirror due to a predetermined amount of electric current being supplied to the second electrode.

16. A semiconductor laser apparatus according to claim 15, wherein the positive electrode is a stripe shape.

17. A semiconductor laser apparatus according to claim 16, wherein at least one positive electrode other than the positive electrode is provided, and the respective positive electrodes are parallel to each other.

18. A semiconductor laser apparatus according to claim 16, wherein the positive electrode is formed so as to have an angle in which a refractive index profile along the direction in which the active layer is extended can be averaged over the entire area of an optical path on which the light is outputted.

19. A semiconductor laser apparatus in which a plurality of cladding layers are laminated; a first electrode having a predetermined width and a second electrode whose width is greater than the width of the first electrode are disposed so as to face one another via the respective cladding layers; a laminating direction of the respective cladding layers at cementing portions of the respective cladding layers is made to be a slab waveguide structure; and a direction vertical to the laminating direction is made to be a gain waveguide structure, and which oscillates a laser beam in these waveguide structures, wherein the first electrode is formed so as to be inclined with respect to an oscillation optical axis of the laser beam.

20. A stack type semiconductor laser apparatus in which a plurality of cladding layers are laminated; a plurality of first electrodes respectively having predetermined widths and a second electrode whose width is greater than the respective widths of the first electrodes are disposed so as to face one another via the respective cladding layers; and a laminating direction of the respective cladding layers at cementing portions of the respective cladding layers is made to be a slab waveguide structure, and which has a plurality of semiconductor lasers forming emission points of a plurality of laser beams due to a direction vertical to the laminating direction being made to be a gain waveguide structure, and which is formed by laminating said plurality of semiconductor lasers, wherein said plurality of first electrodes are respectively formed so as to be inclined with respect to an oscillation optical axes of the laser beams.
